(19) United States
(12) Patent Application Publication
(10) Pub. No.: US 2012/0043518 A1
(43) Pub. Date: Feb. 23, 2012

(54) VARIABLE RESISTANCE MEMORY ELEMENT AND FABRICATION METHODS

(75) Inventors: Siu F. CHENG, Los Angeles, CA (US); Heung Lak PARK, Santa Clara, CA (US); Deenesh PADHI, Sunnyvale, CA (US)

(73) Assignee: APPLIED MATERIALS, INC., Santa Clara, CA (US)

(21) Appl. No.: 12/859,230

(22) Filed: Aug. 18, 2010

(51) Int. Cl. H01L 29/04; H01L 47/00

(52) U.S. Cl. 257/4; 257/2; 438/482; 257/E47.005; 257/E29.003

(57) ABSTRACT

An electronic device comprises a variable resistance memory element on a substrate. The variable resistance memory element comprises (i) an amorphous carbon layer comprising a hydrogen content of at least about 30 atomic percent, and a maximum leakage current of less than about 1×10⁻⁹ amps, and (ii) a pair of electrodes about the amorphous carbon layer. Methods of fabricating this and other devices are also described.

### BACKGROUND

Embodiments of the present apparatus relate to a variable resistance memory element that undergoes a resistive change and is used for memory applications in electronic circuits, and related methods of fabrication.

Electronic circuits, such as integrated circuits, displays and photovoltaic cells, use microprocessor-based systems with a variety of memory devices. The type of memory device depends upon the memory features needed and can include structures that are one-time programmable (such as anti-fuses), rewritable, and volatile or non-volatile memory. As one example, resistive random-access memory (RRAM) are a relatively new type of semi-volatile or non-volatile memory based on resistive switching of variable resistance memory elements. In RRAM's, a variable resistance memory element comprising a dielectric is normally insulating but can be made conductive through one or more filament or conduction paths upon application of a sufficiently high voltage or current. The conduction path formation can arise from different mechanisms, including changes in bonding structures of the resistive switching material. Once the conducting filament is formed, it may be reset to return to a higher resistance state or set to the lower resistance state by appropriately applied voltages. As another example, programmable conductor random access memory (PCRAM) cells and CMOS-compatible field-programmable gate arrays (FPGAs) also use variable resistance memory elements with resistive switching.

In operation, a memory cell comprising a variable resistance memory element stores data by changing the resistance across the memory element in response to a preset voltage or current signal applied to the element. For example, in read-only memory cells, a first value can be written to the memory cell by applying a signal having a predetermined voltage level to the cell, which changes the electrical resistance through the memory cell relative to the resistance of the cell prior to application of the signal. In rewritable cells, a second value (or the default value) may be written to, or restored in, the memory cell by applying a second signal to the memory cell, to change the resistance through the memory cell back to the original level. The second signal has a voltage level in the negative direction from that of the first signal, and the voltage level of the second signal may or may not be the same magnitude as the voltage level of the first signal. Each resistance state is stable so that the memory cells are capable of retaining their stored values without being frequently refreshed. Thus, variable resistance materials operate by being “programmed” or set to a different resistance value which can be reversible or not. Further, the value of a cell can be read or “accessed” by applying a read signal to determine a resistance level across the cell, using a voltage magnitude that is lower than the voltage magnitude required to change the resistance of the cell. If the detected resistance level is greater than the reference level, the memory cell is determined to be in the “off” state, or storing a value of “0”; if the detected resistance level is less than the reference level, the memory cell is determined to be in the “on” state, or storing a value of “1.” However, the absolute or reference resistance values, as well as the change in resistance affected by the application of a known voltage, need to be consistent and stable for reproducible and reliable operation of the PCRAM cell.

Various materials are known to change in resistance with the application of a voltage across the layer to exhibit resistive switching with at least two different resistance states, and thus, such materials are candidates for variable resistance memory elements for memory cells. Some materials being developed include metal oxides, such as Al₂O₃, CuOₓ, HfO₂, MoOₓ, Nb₂O₅, NiOₓ, Ta₂O₅, TiOₓ, WOₓ, and ZrO₂, and amorphous carbon layers. However, amorphous carbon layers are often found to have resistance states that vary from one layer to another and are consequently unreliable. Without being bound by theory, it is believed that the resistance of the amorphous carbon layer changes upon application of a set voltage because the bonding structure of the carbon material changes from SP³ structures to SP² structures. It is further believed that the set voltage heats the amorphous carbon layer to cause the change in bonding structure. However, it is not known why amorphous carbon layers can vary in the levels of their two or more resistance states or in the value of the set voltage to achieve a particular resistance state from one carbon layer to another. This variability in reliably switching between two known resistance states has limited the application of amorphous carbon layers in memory elements and cells.

Another problem with conventional amorphous carbon layers lies in their thermal instability with heat treatment. Certain layers have been known to exhibit good resistance properties prior to exposure to high temperatures but degraded resistance levels after heat treatment. For example, while a resistivity of above 350 ohm-cm, or even above 800 ohm-cm, was measured for these layers prior to treatment, after heat treatment, the resistivity would drop to much lower values of 100 to 200 ohm-cm. Still further, conventional amorphous carbon layers can also exhibit excessive shrinkage after annealing causing the layer to delaminate from the substrate. As result, amorphous carbon layers cannot be used for many structures that include other materials which have to be deposited at high temperatures, such as multi-layer stacks for 3D circuits, arrays, and still others, further limiting their application in memory cell structures.

For various reasons that include these and other deficiencies, and despite the development of various memory cells having variable resistance memory elements that comprise amorphous carbon layers, further improvements in amorphous carbon layers and their fabrication methods are continuously being sought.

### SUMMARY

An electronic device comprises a variable resistance memory element on a substrate. The variable resistance memory element comprises (i) an amorphous carbon layer comprising a hydrogen content of at least about 30 atomic percent, and a maximum leakage current of less than about 1×10⁻⁹ amps, and (ii) a pair of electrodes about the amorphous carbon layer.

An electronic device comprises an amorphous carbon layer disposed on a substrate, the amorphous carbon layer comprising: a hydrogen content of at least about 30 atomic percent and a maximum leakage current of less than about 1×10⁻⁹ amps, the amorphous carbon layer formed by a method comprising: placing the substrate into a process zone; maintaining the substrate at a temperature of less than 300° C.; introducing into the process zone, a process gas comprising a carbon-containing gas and a diluent gas; maintaining the process gas at a pressure of from about 0.5 to about 20 Torr; and forming a plasma from the process gas.

A method of depositing an amorphous carbon layer on a substrate comprises: placing the substrate into a process zone; maintaining the substrate at a temperature of less than 300° C.; introducing into the process zone, a process gas comprising a carbon-containing gas and a diluent gas, and maintaining the process gas at a pressure of from about 0.5 to about 20 Torr; and forming a plasma from the process gas by applying a first RF power at a first frequency to electrodes about the process zone, and applying a second RF power to the substrate at a second frequency, the second frequency being lower than the first frequency.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1A is a schematic diagram of an embodiment of a memory cell comprising a resistance switching element between a pair of electrodes;

FIG. 1B is a schematic diagram of another embodiment of a memory cell comprising a resistance switching element between a pair of electrodes;

FIG. 1C is a schematic diagram of an programmable cell (or anti-fuse cell) comprising a resistance switching element between a pair of electrodes;

FIG. 2 is a sectional schematic side view of a plasma-enhanced chemical vapor deposition apparatus for depositing the amorphous carbon layer;

FIG. 3 is a flowchart of an embodiment of the deposition process for depositing an amorphous carbon layer;

FIG. 4 is a bar chart of the normalized shrinkage of amorphous carbon layers deposited using different deposition processes;

FIG. 5 is a graph of the sheet resistance and resistivity of amorphous carbon layers deposited using different deposition processes;

FIG. 6 is a graph of the breakdown field strength and leakage current of amorphous carbon layers having different hydrogen content;

FIG. 7 is a graph of the breakdown voltage of amorphous carbon layers deposited using different deposition temperatures.

### DESCRIPTION

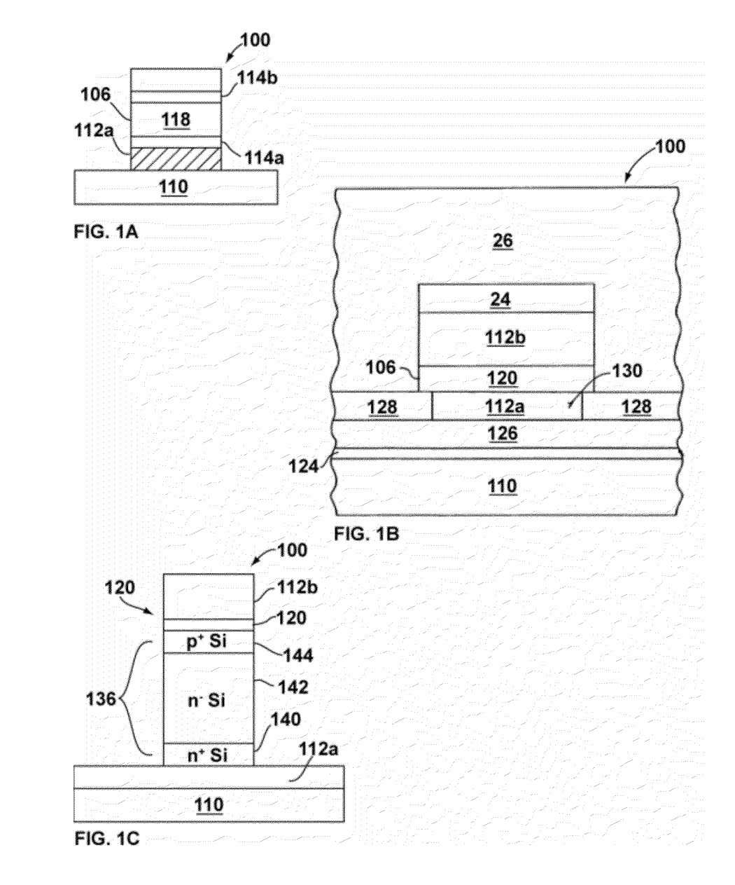

An exemplary embodiment of a memory cell 100 comprising a resistance switching element 106 on a substrate 110 is illustrated in FIG. 1A. The resistance switching element 106 exhibits a defined resistance change from at least a first resistivity (or resistance) to a second resistivity (or resistance) in response to a stimulus signal. The stimulus signal can be, for example, an applied current or voltage or a temperature change. The two different resistivity or resistance (when the aerial size and thickness remain constant) states of the resistance switching element 106 can be used to store information, data, or signals. The memory cell 100 having the variable resistance switching element 106 can be used for different applications, including resistance change memory cells (RRAM), which can be two-dimensional or three-dimensional structures built in layers on the substrate 110. The memory cell 100 can also be rewritable, or one-time programmable such as anti-fuse cells. They allow storage of binary information by switching from a low resistivity to a high resistivity, or vice versa.

The memory cell 100 is formed on a substrate 110 which can be, for example, a semiconductor such as silicon wafer, germanium wafer, or a silicon germanium wafer; a compound semiconductor such as gallium arsenide; or a dielectric such as a glass panel or display, which can include, for example, borophosphosilicate glass, phosphosilicate glass, borosilicate glass, and phosphosilicate glass, polymers, and other materials. In one version, the substrate 110 is a silicon wafer comprising one or more large crystals of silicon. While the exemplary embodiment of the substrate 110 is shown as a single plate-like structure for simplicity, it should be understood that the substrate 110 can and often does include other structures, such as semiconducting structures, polysilicon memory cells, CMOS structures, or still other structures which are formed over an underlying substratum comprising a semiconductor, compound semiconductor, or dielectric material.

A first electrode 112a is formed over the substrate 110 by depositing a layer of conductive material over the substrate 110. Typical deposition processes include physical vapor deposition (PVD) processes, such as sputtering, or chemical vapor deposition (CVD) processes, such as plasma-enhanced CVD or thermally enhanced CVD. For example, in a conventional sputtering process, a target comprising sputtering material is sputtered by a plasma to deposit a conductor layer onto the substrate 110 in a sputtering chamber. A chemical mechanical polishing (CMP) step can be performed to smoothen or flatten the conductive material. In one embodiment, the first electrode 112a is formed of a conductive material comprising an elemental metal such as aluminum (Al), copper (Cu), gold (Au), nickel (Ni), platinum (Pt), doped polysilicon, silver (Ag), titanium (Ti), tungsten (W), zinc (Zn), or mixtures thereof; or conductive metal-containing compounds such as tin-selenide (SnSe), antimony-selenide (SbSe), or silver-selenide (AgSe), tungsten-silicide (WSi). In one version, the first electrode 112a comprises tungsten in a thickness of from about 20 to about 1000 angstroms, such as from about 50 and about 500 angstroms (e.g., about 100 angstroms).

Optionally, a first adhesion layer 114a can be formed on the surface of the first electrode 112a. The first adhesion layer 114a promotes bonding between overlying layers and the electrode 112a and can also serve to electrically isolate the memory cell 100 from the substrate 110. The adhesion layer 114a can be, for example, a layer of an oxide or nitride compound, such as a metal oxide or nitride, using in one version the same metal as the material used for the electrodes 112a,b. For example, when the first electrode 112a is made from tungsten, the adhesion layer 114a comprises tungsten oxide or tungsten nitride or a mixture of the same. The adhesion layer 114a can also comprise adsorbed atoms of oxygen or nitrogen to change the bonding or chemical affinity of atoms at the surface of the first electrode 112a to a subsequently deposited layer. In one example, the surface of the first electrode 112a is treated with an oxygen- and/or nitrogen-containing gas to adsorb oxygen and/or nitrogen atoms onto the surface for bonding with metal atoms in a resistive metal oxide layer, to form a monolayer having a thickness of less than 100 or even about 10 angstroms. In another embodiment, the treated surface of the first electrode 112a forms a solution boundary between the first electrode 112a and an amorphous carbon layer 120, providing improved adhesion by allowing atoms of the carbon layer 120 to intermingle with atoms of the first electrode 112a at the solution boundary. Nitrogen atoms may be adsorbed onto the surface of the first electrode 112a before depositing an amorphous carbon layer 120 to create a solution boundary for the carbon/metal interface. Suitable adhesion layers 114a,b are described in commonly assigned U.S. patent application Ser. No. 12/566,948, by Cheng et al., filed on Sep. 25, 2009, entitled “GLUE LAYER TO IMPROVE AMORPHOUS CARBON TO METAL ADHESION”, which is incorporated by reference herein in its entirety.

The resistance switching element 106 is formed over, or directly on, the first electrode 112a or the adhesion layer 114a. By “over” it is meant there can be one or more intervening layers, and by “directly on” it is meant on and in direct physical contact with the underlayer. In either of these versions, the variable resistance switching element 106 is in electrical contact with the underlying first electrode 112a. In one exemplary embodiment, the resistance switching element 106 comprises at least one resistance switching material 118 capable of transitioning from a higher to a lower resistivity state, or resistance value, in a set transition which is controlled by a set stimulus signal, such as a set current, set or programming voltage, or set or programming pulse. The reverse transition from a lower to a higher resistivity state is called a reset transition, which is affected by a reset current, a reset voltage, or a reset pulse which places the resistance switching element 106 in an un-programmed state.

In one exemplary embodiment, the resistance switching material 118 comprises, or consists essentially of, an amorphous carbon layer 120. The amorphous carbon layer 120 can contain amorphous carbon without long-range order, microcrystalline carbon, glassy carbon, graphene, or even carbon nanotubes that are single-walled, multi-walled, or a mixture of single- and multi-walled nanotubes. The amorphous carbon layer 120 can also include other elements, such as hydrogen, nitrogen or oxygen. In one version, the amorphous carbon layer 120 has a thickness of from about 100 to about 1000 angstroms, or even from about 100 to about 500 angstroms, (e.g., about 300 angstroms). In a further embodiment, the amorphous carbon layer 120 has a sheet resistance (“Ω/□” or “ohms/square”) of from about 1×10⁷Ω/□ to about 1×10⁸Ω/□ for a layer having a thickness of about 2000 angstroms. While the resistance switching element 106 as shown comprises a resistance switching material 118 that is an amorphous carbon layer 120, the resistance switching element 106 can also be solely composed of other materials or comprise combinations of other materials or layers. For example, other suitable resistance switching materials can include nickel oxide or carbon-hydrogen materials, which can be used singly or in combination with the amorphous carbon layer 120. Also, the resistance switching material can include other elements, such as silicon, nitrogen, and hydrogen, which are often found in amorphous carbon materials.

Again, optionally, a second adhesion layer 114b can be formed on the surface of the resistance switching material 118. The second adhesion layer 114b promotes bonding between the resistance switching material 118 and overlying layers, such as the second electrode 112b, and can also serve to electrically isolate the memory cell 100 from the substrate 110. The second adhesion layer 114b can be the same material as the first adhesion layer 114a, e.g., a layer of a metal nitride such as, for example, titanium nitride.

A second electrode 112b is formed over the resistance switching material 118 by depositing a layer of conductive material over the substrate 110. The second electrode 112b can be made from the same conductive material as the first electrode 112a and deposited by the same deposition process or a different deposition process. A chemical mechanical polishing (CMP) step can be performed to smoothen or flatten the conductive material. In one embodiment, the second electrode 112b is also formed of a conductive material comprising an elemental metal such as aluminum, copper, titanium, or tungsten. However, other materials such as tungsten silicide or tungsten nitride can also be used.

In use, the memory cell 100 can be operated as a one-time programmable, or a rewritable memory element, by reversibly switching the resistivity of the resistance switching material 118 between two or more resistance states. For example, the resistance switching material 118 may be in an initial, low-resistivity state upon fabrication which switches to a high-resistivity state upon application of a first preset voltage or current and returns to low-resistivity state upon application of a second voltage or current. Alternatively, the resistance switching material 118 can be in an initial, high-resistance state upon fabrication that is reversibly switchable to a low-resistance state upon application of a second preset voltage or current. Thus, during operation of the memory cell 100, one resistance state may represent an “off” state, such as a binary “0”, whereas another resistance state may represent an “on” state, such as a binary “1”, although more than two data/resistance states may be used. In one version, the resistance switching material 118 has a resistivity in an “on”-state of <10 ohm-cm, for example, from about 0.001 ohm-cm to about 10 ohm-cm; and in an “off”-state of at least 300 ohm-cm, for example, from about 200 to about 1000 ohm-cm.

A second embodiment of a memory cell 100 is illustrated in FIG. 1B. In this embodiment, an isolation layer 124 is deposited on the substrate 110 to electrically isolate the memory cell 100 from the substrate 110. The isolation layer 124 can also serve as an adhesion layer which promotes bonding between overlying layers and the substrate 110. The isolation layer 124 can be, for example, an insulator such as silicon oxide, silicon nitride, silicon oxynitride, or other insulating materials.

A conductive address line 126 serves as an interconnect-line for the memory cell 100, or a plurality of memory cells that form a memory array (not shown). The conductive address line 126 is made by depositing a conductive material onto the substrate 110, such as, for example, the previously described materials used for the first and second electrodes 112a,b, and deposited by the same processes. In one version, the address line 126 comprises tungsten in a thickness of from about 200 to about 2000 angstroms.

An insulator layer 128 is over the address line 126 to prevent the diffusion or migration of atoms of the conductive material from the address line 126 or other such layers. For example, the insulator layer 128 can be, for example, a dielectric material such as silicon nitride (Si₃N₄); a low dielectric constant material such as Black Diamond™ from Applied Materials, Santa Clara, Calif.; or an insulating glass such as TEOS-deposited silicon oxide. Such layers can be deposited by conventional CVD or PVD methods and patterned to form apertures 130 using photolithographic and etching methods.

In this version, a first electrode 112a is formed within the aperture 130 in the insulator layer 128 by forming a layer of conductive material over the aperture 130 and insulator layer 128, and then polishing or etching off the excess conductive material deposited outside the aperture 130.

The resistance switching element 106 is formed over the first electrode 112a. For example, a resistance switching element 106 comprising an amorphous carbon layer 120, as previously described, can be formed on the first electrode 112a to be in electrical contact with the first electrode 112a. The amorphous carbon layer 120 has the same properties as, and is deposited using the same methods, as the previously described version.

A second electrode 112b is formed over the amorphous carbon layer 120 of the resistance switching element 106 as previously described. In operation, it is believed that upon application of a conditioning voltage, metal ions from the first or second electrodes 112a,b diffuse into the amorphous carbon layer 120 to form conducting channels in the carbon layer 120. For example, it is believed that upon the application of a voltage, a metal ion enters the amorphous carbon layer 120 and donates an electron to a carbon-to-carbon double bond between sp² hybridized carbon atoms such that the sp² hybridized carbon atoms form the conducting channels between the sp³ hybridized carbon atoms. A subsequently applied write voltage with a lower energy than that of the conditioning voltage can reverse the process to program the amorphous carbon layer 120 to a lower resistance state.

In yet another embodiment, the memory cell 100 includes a controlling element 134, such as a transistor or a diode, which operates in conjunction with the resistance switching element 106. FIG. 10 shows a memory cell 100 comprising a controlling element 134 that is a semiconductor diode 136. The semiconductor diode 136 includes a bottom n-type doped region 140, an intrinsic region 142, and a top p-type doped region 144. The intrinsic region 142 can have a low concentration of p-type or n-type dopants which can be implanted into this region or which can diffuse into this region from adjacent n- or p-doped regions 140, 144, respectively. Alternative or reversed orientations (for example, with the p-type doped region at the bottom) can also be used. Also, the resistance switching element 106, which serves as the memory storage element, can be located above or below the diode 136. The diode 136 can be made from conventional semiconductor materials, such as, for example, single or polycrystalline forms of silicon, germanium, or silicon-germanium alloys. The diode 136 and a resistance switching element 106, comprising an amorphous carbon layer 120, are positioned between the first and second electrodes 112a,b. Adhesion and isolation layers can also be included above or below the electrodes 112a,b. The memory cell 100 can be put into distinct data states by a series of distinct forward voltage biases. The current flowing through the memory cell 100 between any distinct data state and any other distinct data state is different such that the differences between the states can be readily detectable.

In one embodiment, the amorphous carbon layer 120 is deposited using a chemical vapor deposition (CVD) process, such as a plasma-enhanced chemical vapor deposition (PECVD) process. However, the amorphous carbon layer 120 can be formed by other deposition processes as would be apparent to those of ordinary skill in the art. For example, the amorphous carbon layer 120 can also be deposited by, including without limitation, PVD sputter deposition from a target, thermal CVD processes, and other methods.

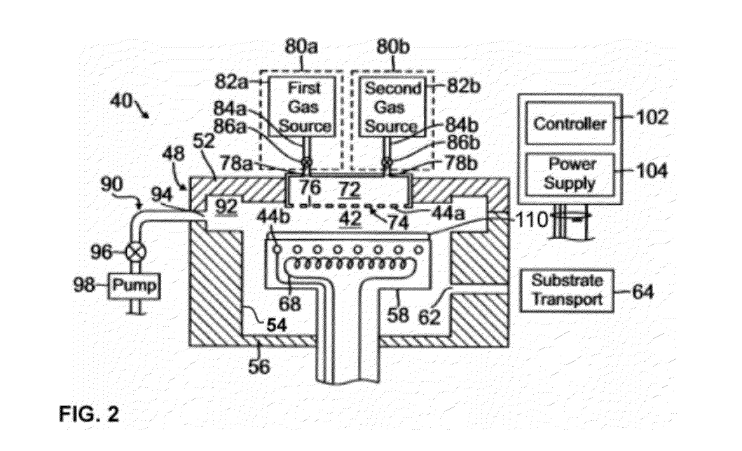

A suitable plasma-enhanced chemical vapor deposition (PECVD) chamber 40, as illustrated in FIG. 2, comprises enclosure walls 48 which include a ceiling 52, sidewalls 54, and a bottom wall 56, that enclose a process zone 42. The chamber 40 may also comprise a liner (not shown) that lines at least a portion of the enclosure walls 48 about the process zone 42. For processing a 300 mm silicon wafer, the chamber 40 typically has a volume of about 20,000 to about 30,000 cm³, and more typically about 24,000 cm³. In one version, the chamber 40 is a Producer® SE type chamber from Applied Materials, Santa Clara, Calif.

During processing, a substrate support 58 is lowered and a substrate 110 is passed through an inlet port 62 and placed on the support 58 by a substrate transport 64, such as a robot arm. The substrate support 58 can be moved between a lower position for loading and unloading and an adjustable upper position for processing of the substrate 110. The substrate support 58 can include an enclosed process electrode 44b to generate a plasma from process gas introduced into the chamber 40. The substrate support 58 can be heated by heater 68, which can be an electrically resistive heating element (as shown), a heating lamp (not shown), or the plasma itself. The substrate support 58 typically comprises a ceramic structure which has a receiving surface to receive the substrate 110, and which protects the process electrode 44b and heater 68 from the chamber environment. In use, a radio frequency (RF) voltage is applied to the process electrode 44b and a direct current (DC) voltage is applied to the heater 68. The process electrode 44b in the substrate support 58 can also be used to electrostatically clamp the substrate 110 to the support 58. The substrate support 58 may also comprise one or more rings (not shown) that at least partially surround a periphery of the substrate 110 on the support 58.

After a substrate 110 is loaded onto the support 58, the support 58 is raised to a processing position that is closer to the gas distributor 72 to provide a desired spacing gap distance, dₛ, therebetween. A suitable spacing distance is from about 200 mils to about 1000 mils (or from about 0.5 to about 2.5 cm). The gas distributor 72 is located above the process zone 42 for dispersing a process gas uniformly across the substrate 110. The gas distributor 72 can separately deliver two independent streams of first and second process gas to the process zone 42 without mixing the gas streams prior to their introduction into the process zone 42, or the gas distributor 72 can premix the process gas before providing the premixed process gas to the process zone 42. The gas distributor 72 comprises a faceplate 74 having holes 76 that allow the passage of process gas therethrough. The faceplate 74 is typically made of metal to allow the application of a voltage or potential thereto, thereby serving as process electrode 44a in the chamber 40. A suitable faceplate 74 can be made of aluminum with an anodized coating.

The substrate processing chamber 40 also comprises first and second gas supplies 80a,b to deliver the first and second process gas to the gas distributor 72, the gas supplies 80a,b each comprising a gas source 82a,b, one or more gas conduits 84a,b, and one or more gas valves 86a,b. For example, in one version, the first gas supply 80a comprises a first gas conduit 84a and a first gas valve 86a to deliver a first process gas from the first gas source 82a to a first inlet 78a of the gas distributor 72, and the second gas supply 80b comprises a second gas conduit 84b and a second gas valve 86b to deliver a second process gas from the second gas source 82b to a second inlet 78b of the gas distributor 72.

The process gas can be energized by coupling electromagnetic energy (e.g., high frequency voltage energy) to the process gas to form a plasma from the process gas. To energize the first process gas, a voltage is applied between (i) a first process electrode 44a, which may be the gas distributor 72, ceiling 52, or sidewall 54, and (ii) a second process electrode 44b in the support 58. The voltage applied across the pair of process electrodes 44a,b capacitively couples energy to the process gas in the process zone 42. Typically, the voltage applied to the process electrodes 44a,b is an alternating voltage which oscillates at a radio frequency. Generally, radio frequencies cover the range of from about 3 kHz to about 300 GHz. For the purposes of the present application, low radio frequencies are those which are less than about 1 MHz, and more preferably from about 100 KHz to 1 MHz, such as, for example, a frequency of about 300 KHz. Also for the purposes of the present application, high radio frequencies are those from about 3 MHz to about 60 MHz, and more preferably about 13.56 MHz. The selected radio frequency voltage is applied to the process electrode 44a at a power level of from about 10 W to about 1000 W, and the process electrode 44b is typically grounded. However, the particular radio frequency range that is used and the power level of the applied voltage depend on the type of material to be deposited.

The chamber 40 also comprises a gas exhaust 90 to remove spent process gas and byproducts from the chamber 40 and maintain a predetermined pressure of process gas in the process zone 42. In one version, the gas exhaust 90 includes a pumping channel 92 that receives spent process gas from the process zone 42, an exhaust port 94, a throttle valve 96, and one or more exhaust pumps 98 to control the pressure of process gas in the chamber 40. The exhaust pumps 98 may include one or more of a turbomolecular pump, cryogenic pump, roughing pump, and combination-function pumps that have more than one function. The chamber 40 may also comprise an inlet port or tube (not shown) through the bottom wall 56 of the chamber 40 to deliver a purging gas into the chamber 40. The purging gas typically flows upward from the inlet port past the substrate support 58 and to an annular pumping channel. The purging gas is used to protect surfaces of the substrate support 58 and other chamber components from undesired deposition during the processing. The purging gas may also be used to affect the flow of process gas in a desirable manner.

A controller 102 is also provided to control the operation and operating parameters of the chamber 40. The controller 102 may comprise, for example, a processor and memory. The processor executes chamber control software, such as a computer program stored in the memory. The memory may be a hard disk drive, read-only memory, flash memory, or other types of memory. The controller 102 may also comprise other components, such as a floppy disk drive and a card rack. The card rack may contain a single-board computer, analog and digital input/output boards, interface boards, and stepper motor controller boards. The chamber control software includes sets of instructions that dictate the timing, mixture of gases, chamber pressure, chamber temperature, microwave power levels, high frequency power levels, support position, and other parameters of a particular process.

The chamber 40 also comprises a power supply 104 to deliver power to various chamber components such as, for example, the first process electrode 44a in the chamber and the second process electrode 44b in the substrate support 58. To deliver power to the process electrodes 44a,b, the power supply 104 comprises a radio frequency voltage source that provides a voltage having the selected radio frequencies and the desired selectable power levels. The power supply 104 can include a single radio frequency voltage source or multiple voltage sources that provide both high and low radio frequencies. The power supply 104 can also include an RF matching circuit. The power supply 104 can further comprise an electrostatic charging source to provide an electrostatic charge to an electrode 44a,b, often an electrostatic chuck in the substrate support 58. When a heater 68 is used within the substrate support 58, the power supply 104 also includes a heater power source that provides an appropriate controllable voltage to the heater 68. When a DC bias is to be applied to the gas distributor 72 or the substrate support 58, the power supply 104 also includes a DC bias voltage source that is connected to a conducting metal portion of the faceplate 74 of the gas distributor 72. The power supply 104 can also include the source of power for other chamber 40 components, for example, motors and robots of the chamber.

The temperature of the substrate 110 during the deposition process can vary between 100, 200 and 300° C. The temperature was measured using a temperature sensor (not shown), such as a thermocouple or an interferometer, to detect the temperature of the substrate support 58 within the chamber 40. The temperature sensor is capable of relaying its data to the chamber controller 102 which can then use the temperature data to control the temperature of the processing chamber 40, for example, by controlling the resistive heating element in the substrate support 58.

An exemplary deposition process and/or a sequence of deposition processes will now be described. In these processes, a substrate 110 having an already deposited first electrode 112a is placed in the process zone 42 of the chamber 40. As previously described, the first electrode 112a can be deposited by conventional PVD or CVD processes in this chamber or in other apparatus. Initially, and optionally, the surface of the first electrode 112a is treated to form an adhesion layer 114 so that the amorphous carbon layer 120 can be deposited over the first electrode 112a. In one version, the adhesion layer 114 comprises a monolayer or more of atoms of oxygen and/or nitrogen, formed on the amorphous carbon layer 120. For example, the adhesion layer 114 can be a continuous or discontinuous layer up to about 5 monolayers thick, which may have a thickness less than about 10 angstroms. The average saturation of the surface of the electrode layer 112a with adhesion-promoting materials may vary between about 50% and about 100%, such as between about 75% and about 100% (e.g., about 98% or more). In one version, nitrogen is added to a surface of the metal of electrode 112a to form a nitrogen-rich surface by exposing the substrate 110 to a nitrogen-containing gas. The nitrogen-containing gas may be ionized in the chamber 40 by coupling an inductive or capacitative electric field into the process zone 42. Nitrogen-containing ions formed thereby may be encouraged to deposit on, or impact with, the surface of the first electrode 112a by biasing the substrate 110. The nitrogen-containing ions occupy adsorption sites on the surface of the first electrode 112a, and some nitrogen-containing ions embed or implant into the surface of the first electrode 112a, depending on the bias energy of the substrate 110. A weak bias, such as an RF bias between about 100 V and about 500 V, root-mean-square, at a power level less than about 500 watts, may be used for a shallow surface treatment with nitrogen-containing ions. In some embodiments, the nitrogen-containing ions may deposit on the surface of the first electrode 112a to an average depth of less than about 5 monolayers. In other embodiments, the nitrogen-containing ions may deposit to an average depth less than about 10 angstroms.

In one embodiment, nitrogen may be added to the surface of a first electrode 112a by exposing the surface to a plasma comprising nitrogen. A nitrogen-containing gas mixture is provided to a process chamber 40 through the gas distributor 72, and the substrate 110 is disposed on the substrate support 58 within the process zone 42. The substrate support 58, the gas distributor 72, or both, are coupled to a source of electrical energy, which may be DC, pulsed DC, or RF energy provided through an impedance matching circuit. The electrical energy ionizes the nitrogen-containing gas mixture into a plasma which interacts with the surface of the first electrode 112a. The nitrogen-containing gas mixture may comprise nitrogen gas (N₂), ammonia (NH₃), nitrous oxide (NO₂) or hydrazine (H₂N₂), and may further comprise a carbon-containing gas such as methane (CH₄), ethane (C₂H₆), ethylene (C₂H₄), or acetylene (C₂H₂). Including carbon in the nitrogen-containing gas mixture may be advantageous for embodiments in which the resistive layer comprises amorphous carbon or doped amorphous carbon. The nitrogen-containing gas mixture is generally provided to the process chamber at a flow rate between about 10 sccm and about 10,000 sccm, such as between about 500 sccm and about 8,500 sccm (e.g., between about 7,500 sccm and about 8,500 sccm), or between about 3,500 sccm and about 4,500 sccm, between about 1,500 sccm and about 2,500 sccm, or between about 500 sccm and about 1,500 sccm. Adhesion may be controlled by exposure time which may influence the degree of saturation of the surface of the first electrode 112a layer with nitrogen, or by the volumetric ratio of nitrogen-containing species to nitrogen-free species or to the total gas mixture.

In one embodiment, an electrode 112a comprising tungsten is treated by exposure to a gas mixture comprising nitrogen gas (N₂) and acetylene (C₂H₂) at a volumetric ratio of N₂/C₂H₂ of between about 1:1 and about 40:1, such as between about 1:1 and about 20:1, or between about 20:1 and about 40:1, or between about 1:1 and about 5:1, or between about 5:1 and about 10:1, or between about 10:1 and about 20:1, or between about 20:1 and about 40:1. Plasma generation power is provided at between about 1,000 watts and about 5,000 watts, such as between about 1,500 watts and about 3,000 watts. Exposure to such conditions for a time between about 10 seconds and about 500 seconds, such as between about 50 seconds and about 250 seconds (e.g., between about 100 seconds and about 200 seconds), improves adhesion of a carbon-containing layer to the tungsten surface. In one embodiment, nitrogen gas is provided to the chamber 40 at a flow rate of 8,000 sccm and acetylene gas at 200 sccm, and plasma power is applied at 1,600 watts at a temperature of 400° C. and a pressure of 6.5 mTorr for 40 seconds to produce a treated tungsten surface having good adhesion to a carbon resistive layer.

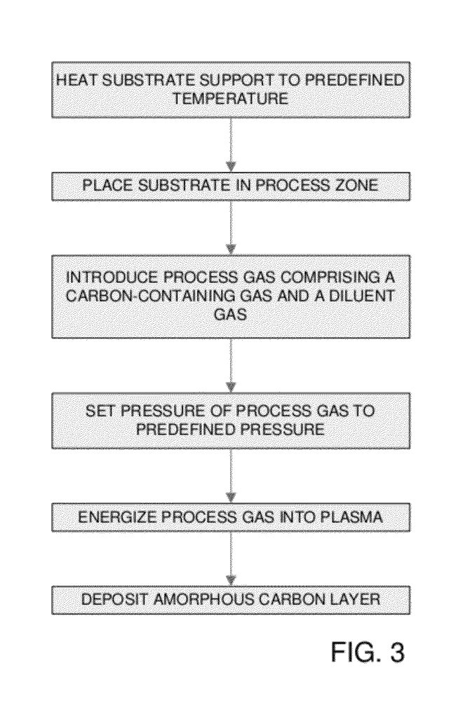

An amorphous carbon layer 120 is then deposited on the substrate 110 after deposition of the optional adhesion layer 114 or directly on the first electrode 112a, or over other intervening layers. An exemplary embodiment of a process for depositing an amorphous carbon layer 120 is illustrated in FIG. 3. The process zone 42 of the chamber 40 is maintained at vacuum by controlling the pressure of process gas introduced into the process zone 42. A substrate 110 is placed on the substrate support 58 in the process zone 42, and the substrate support 58 is heated to a desired deposition temperature. Suitable deposition temperatures range from about 100 to about 400° C.

Before or after placing the substrate 110 in the process zone 42, a process gas comprising a carbon-containing gas and a diluent gas is introduced into the chamber 40. The carbon-containing gas provides carbon for the amorphous carbon layer 120 to be deposited. The carbon-containing gas may include, but is not limited to, one or more carbon-containing gases such as CₓH_{y} where x is from 1 to 10 and y is from 2 to 30. For example, the carbon-containing gases can include, without limitation, gases such as CH₄, C₂H₂, C₂H₄, C₂H₆, C₃H₄, C₃H₆, C₃H₈, C₄H₁₀ or mixtures thereof. The carbon-containing gases can also be triethylamine, or even CₓH_{y}N_{z} where x is from 1 to 10, y is from 2 to 30, and z is from 1 to 10. In a further embodiment, the process gas includes a carbon-containing gas which is absent oxygen to avoid an oxygenating environment that can burn out the deposited carbon layer 120. In one version, the carbon-containing gas is provided in a volumetric flow rate of from about 200 sccm to about 3000 sccm, or even from about 200 sccm to about 1000 sccm.

The process gas further comprises a diluent gas that provides better film thickness uniformity across the substrate 110 for the deposited amorphous carbon layer 120. For example, the diluent gas can provide a larger number of energized gas ions through increased collisions of gas molecules or by transporting molecules of the carbon-containing gas across the chamber 40. Suitable diluent gases include, but are not limited to, one or more of argon, helium, hydrogen or nitrogen, or mixtures thereof. In one version, the diluent gas is provided in a flow rate of from about 100 to about 10,000 sccm, or even from about 200 to about 5000 sccm, or even from about 300 to about 3000 sccm.

In any of these versions, the process gas in the process zone 42 is energized by applying a voltage or current of RF (or radio frequency) energy to the process electrodes 44a,b about the process zone 42. The process electrodes 44a,b can be spaced apart at a spacing distance of from about 0.5 cm (0.2 in) to about 13 cm (5 in). In one version, a first RF power is applied at a first frequency to the process electrodes 44a,b at a power level of from about 50 to about 2000 watts. The first RF power can be, for example, at a frequency of about 13.5 MHz. A second RF power is applied directly to the substrate 110 by applying electrical power to the substrate support 58 supporting the substrate 110. The second RF power can be applied at a second frequency that is lower than the first frequency; for example, the second frequency can be less than 1 MHz. In one version, the second RF power is at a power level of from about 100 to about 2000 watts. Energizing the plasma by the combination of different frequencies of RF power allows the control of film density and hardness for tuning thermal stability of the films.

During the deposition process, the process zone 42 is maintained at a temperature of from about 50 to about 650° C., or even from 100 to about 300° C. The process temperature was found to increase and control the atomic percentage ratio of carbon to hydrogen in the deposited film. For example, formation of the amorphous carbon layer 120 at a temperature of 550° C. provided a hydrogen content of less than 20%.

The amorphous carbon layer 120 that is deposited using these deposition processes can be formed with a thickness that depends on the application. In one embodiment, the amorphous carbon layer 120 is deposited to a thickness of from about 50 to about 1000 angstroms, or even from about 50 to about 300 angstroms.

### EXAMPLES

The following illustrative examples demonstrate the effectiveness and advantages of the memory cell 100 and deposition processes described herein. The memory cell 100 and methods described herein will become better understood with regard to these illustrative examples. However, it should be understood that each of the features described herein can be used by itself or in any combination with each other, and not merely as described in a particular example.

In these illustrative examples, various properties of the deposited amorphous carbon layers 120 were measured in relation to processing conditions. These samples were processed at the processing conditions shown in Table I.

TABLE I
Processing conditions of High Dep. Rate Films

| | | | | | | High | | | |
|---|---|---|---|---|---|---|---|---|---|
| | | | | | | Freq RF | Low Freq RF | | |
| | Temp | C₂H₂ | He | Ar | H₂ | Power | Power | Spacing | Pressure |
| Film | (C.) | sccm | sccm | sccm | sccm | (watts) | (watts) | (mils) | (Torr) |
| iC1 | 200 | 600 | 400 | 13800 | 0 | 1400 | 0 | 250 | 3.5 |
| iC2 | 200 | 1500 | 400 | 13800 | 2000 | 1000 | 0 | 250 | 3.5 |
| iC3 | 200 | 1500 | 400 | 13800 | 2000 | 700 | 300 | 250 | 3.5 |

TABLE II
Processing conditions of Low Dep. Rate Films

| | LDRiC 1 | LDRiC 2 | LDRiC 3 | LDRiC 4 |
|---|---|---|---|---|
| Temp | 200 | 200 | 200 | 200 |
| C₂H₂ | 700 | 750 | 300 | 300 |
| He | 0 | 200 | 3000 | 3000 |
| Ar | 0 | 6900 | 1000 | 0 |
| H₂ | 7000 | 3000 | 4500 | 4500 |
| HFRF | 100 | 1000 | 100 | 300 |
| LFRF | 300 | 0 | 300 | 300 |
| Spacing | 400 | 300 | 400 | 400 |
| Press | 3 | 1.75 | 3 | 3 |
| Density | 1.4071 | 1.541 | 1.4733 | 1.4733 |
| Stress | −265 | −329 | −176 | −226 |
| n633 | 1.841 | 1.893 | 1.873 | 1.895 |
| k633 | 0.053 | 0.086 | 0.066 | 0.069 |
| GOF | 0.986 | 0.953 | 0.984 | 0.982 |
| R/2 | 6.63 | 6.96 | 6.08 | 4.39 |
| DR | 1297 | 2343 | 753 | 797 |

The film properties of selected samples were measured as shown in Table II and include density, stress, extinction coefficient value (k633), deposition rate in angstroms/minute, and post-annealing thickness percent change and resistivity properties after annealing at 650° C. for one hour in nitrogen. It was found that the density was a good indicator of the stability of the amorphous carbon layers 120 after annealing. Specifically, a density of at least about 1.4, or even at least about 1.45, was desirable to achieve thermally stable films. In one example, the amorphous carbon layers 120 had an average density value of from about 1.40 to about 1.55 g/cc. Suitable stress values ranged from about −100 to about −400 MPa. The desirable temperature-stable amorphous carbon layers 120 also had a first resistivity level that is greater than 400 ohm-cm and a sheet resistance of greater than 1×10⁸ ohms/sq.

TABLE III
Properties of selected amorphous carbon layers deposited in Table I

| | | | | | | Post 1-hr | |
|---|---|---|---|---|---|---|---|
| | | | | | | 650 C. | |
| | | | | | | Anneal | Post Anneal |
| | | | | | DR | Thickness | Resistivity |
| Film | Density | Stress | n633 | k633 | (Å/min) | Change (%) | Performance |
| AC-2 | 1.187 | −883.9 | 1.708 | 0.003 | 347 | −57.82 | Baseline |
| anneal | | | | | | | |
| iC1 | 1.600 | −529.5 | 2.042 | 0.132 | 4231 | 2.30 | Comparable to |
| | | | | | | | baseline |
| iC2 | 1.507 | −282.4 | 1.915 | 0.067 | 7121 | −2.80 | 10x improvement |
| | | | | | | | over baseline |
| iC3 | 1.507 | −216.6 | 1.902 | 0.064 | 5488 | −5.83 | 10x improvement |
| | | | | | | | over baseline |

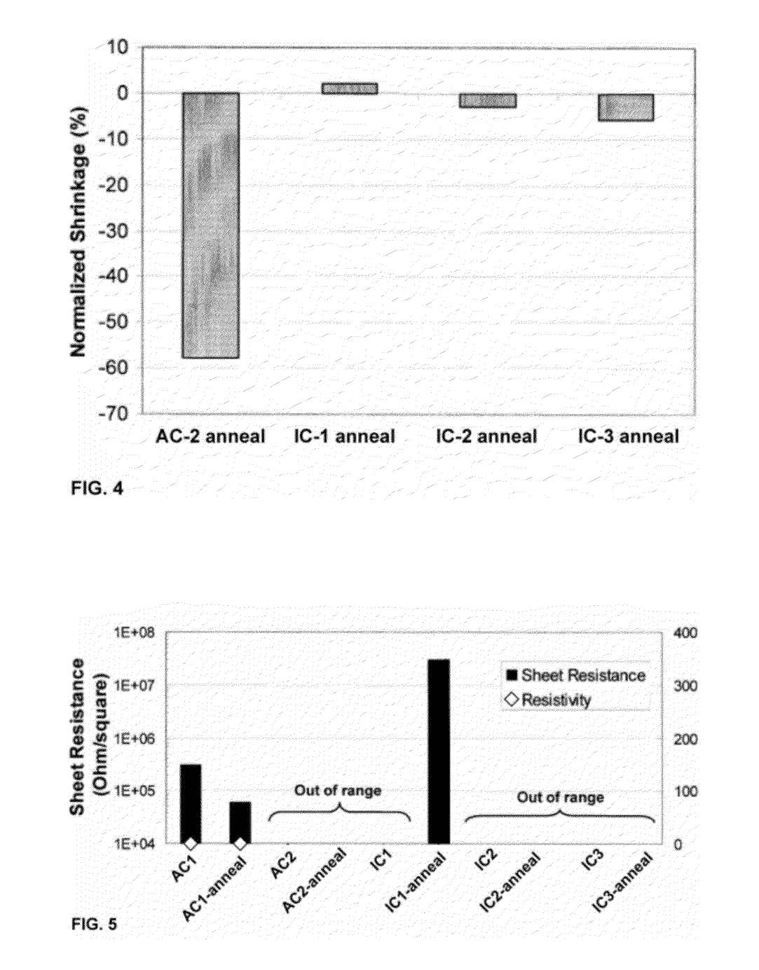

Referring to Table I and FIG. 4, which shows the shrinkage in a bar chart form, one of the desirable properties to be achieved in the deposited amorphous carbon layers 120 is low thermal shrinkage. A layer 120 which has low thermal shrinkage is desirable to prevent delamination or spalling of the amorphous carbon layers 120 from the underlying substrate 110 during the amorphous carbon deposition process or during other post-deposition processes. Thermal shrinkage is especially a problem when subsequent processing of this or other layers on the substrate 110—which may include dielectric layers, interconnect layers, ion implantation structures, and others—are performed at temperatures exceeding 500° C., or even temperatures exceeding 600° C.

It was found that the baseline sample (AC-2 anneal) had an excessively high thermal shrinkage of about 57% after annealing for 1 hour at 650° C. in N₂ gas. In contrast, samples IC1, IC2 and IC3 exhibited low thermal shrinkage of less than about 10%, or even less than 5%. Some of these samples had a thermal shrinkage of less than 3%, which is highly desirable. There is also an apparent correlation between the density of the deposited amorphous carbon layer 120 and the post-anneal thermal shrinkage percentage. It was determined that amorphous carbon layers 120 having a density of greater than 1.45 were desirable to produce thermal shrinkage of less than about 5%. In addition, the deposition processing conditions used for samples IC1 to IC3 provided substantially higher deposition rates of greater than 4000 angstroms/minute relative to the baseline sample which had a deposition rate of about 350 angstroms/minute. This represented a tenfold increase in deposition rate.

The sheet resistance and resistivity of a number of different amorphous carbon layers 120 processed at different processing conditions is shown in FIG. 5. In these examples, the sheet resistance was measured on a KLA-Tencor OmniMAP™, available from Milpitas, Calif. A 4-point, “B” type probe was used for the measurements with a measurement range of up to 1×10⁸ ohm/square (approximately 350 ohm-cm for 2 kA thickness). The resistivity was calculated from the sheet resistance using the film thickness t, with the formula Rs (sheet resistance in ohms/square) layer=t (thickness in cm)×p (resistivity in ohm-cm).

It has been found that the resistivity of the amorphous carbon layer 120 is approximately inversely proportional to the extinction coefficient measured at 633 nanometers. The extinction coefficient is related to the amount of light that is absorbed by the material. In optics, the extinction coefficient (k) occurs in the complex expression for the index of refraction (ñ). Where each of ñ, n and k are functions of the frequency of the incident radiation, the complex index of refraction is:

ñ(f)=n(f)+ik(f)

The extinction coefficient can be somewhat easier to measure than the resistivity, because it can be measured without having to physically contact the film with electrical terminals, and depends more on the film composition than the dimensions of the piece of film being measured. For example, the extinction coefficient can be measured by shining a light beam of known wavelength and intensity onto a known thickness of material, and measuring the percentage of incident light that is reflected from the medium and transmitted through the medium. The measured percentages of reflected and transmitted light can be used to calculate the amount of light absorbed by the medium, and used to calculate the extinction coefficient. The extinction coefficient provides an alternative means for characterizing the deposited amorphous carbon film. The extinction coefficient is desirably a low number, for example the extinction coefficient of the amorphous carbon layer, measured with 633 nm light, is desirably less than about 0.4 or even less than about 0.35 or even less than about 0.1, such as from about 0.03 to about 0.1.

Referring to FIG. 5, amorphous carbon layer sample AC1 exhibited a sheet resistance of about 2×10⁵ ohms/square and a resistivity of about 120 ohms-cm. These resistance values were too low for the layer to be acceptable. The AC1-anneal sample was the same sample as AC1, measured after annealing the layer for 15 minutes at 650° C. in a nitrogen atmosphere. The resistance values dropped even lower with a sheet resistance of about 5.5×10⁴ ohms/square and a resistivity of 55 ohms-cm. Thus, the AC1 sample was also not resistant to thermal anneals.

Sample AC2 exhibited a resistance that was out of range of the measurement scale that was greater than 1×10⁸ ohms/square and a resistivity greater than 400 ohms-cm, both of which are desirable resistance properties. AC2-anneal is the same sample as AC2 but after annealing the layer for 1 hour at 650° C. in nitrogen. AC2-anneal maintained a high resistance out of range of the measurement scale, i.e., greater than 1×10⁸ ohms/square and with a resistivity of greater than 400 ohms-cm, both of which were desirable properties. However, the AC2-anneal sample also showed unacceptably high thickness shrinkage values with a thickness change of greater than 50%, namely about 57%, after annealing as shown in Table II.

The amorphous carbon layer of sample IC1 exhibited good resistance values, which were out of range of the measurement scale, i.e, greater than 1×10⁸ ohms/square and with a resistivity greater than 400 ohms-cm. However, the IC1-anneal sample which was annealed for one hour at 650° C. in nitrogen exhibited resistance values which were too low, although the thickness shrinkage values were acceptable at less than 5%, namely 2.3%, as shown in Table II. The low resistance values after annealing made the IC1 layer unacceptable.

The amorphous carbon layers IC2 and IC3 both exhibited high and acceptable resistance values, i.e., greater than 1×10⁸ ohms/square and with a resistivity of greater than 400 ohms-cm, even after annealing of these samples for 1 hour at 650° C. in nitrogen, as shown by IC2-anneal and IC3-anneal. Further, the thickness shrinkage values were also good at less than 10%, namely 2.8% and 5.8%, as shown in Table II. These two amorphous carbon layers 120 had a sheet resistance of greater than 1×10⁸ ohms/square and a resistivity greater than 400 ohms-cm after annealing, and also had a low thermal shrinkage after annealing of less than 10%, or even less than 5%.

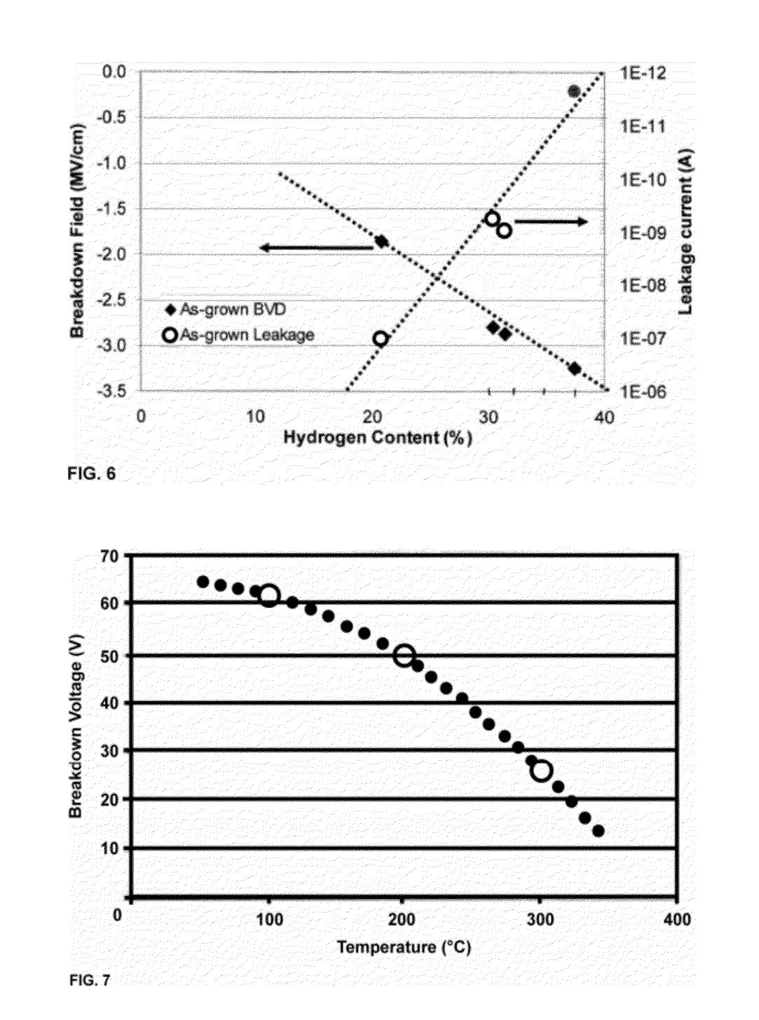

The electrical properties of the IC sample layers as a function of their hydrogen content is shown in FIG. 6. It was discovered that the hydrogen content of the amorphous carbon layers 120 was a significant factor that affected their breakdown field strengths and leakage currents. More specifically, the amorphous carbon layers 120 with higher hydrogen contents had lower leakage currents. Further, it was determined that, for as-grown amorphous carbon layers 120 (without any annealing), a hydrogen atomic percent content of at least 30% is desirable to obtain an amorphous carbon layer 120 having a leakage current of at least about 1×10⁻⁹ amps and a breakdown field strength more than about −2.5 MV/cm.

It is believed that setting deposition conditions such that the amorphous carbon layers 120 have a hydrogen content of greater than 30% provides desirable properties of breakdown field strength and leakage current. It is further believed that desirable amorphous carbon layers 120 have an amorphous or non-crystalline structure and contain carbon that is bonded with both sp² and sp³ hybridized carbon bonds. The ratio of sp² and sp³ hybridized carbon varies from one amorphous carbon layer 120 to another depending on deposition process conditions. However, increasing the number of hydrogen atoms in an amorphous carbon layer 120 changes the bonding structure in the carbon layer to provide a greater ratio of sp³ hybridized carbon relative to sp² hybridized carbon. With increasing sp³ content, the bonding network is stronger due to increased coordination between the atoms. Further, the lower amount of sp² hybridized carbon, as represented by the higher hydrogen content in the layers, also provides a higher sheet resistance and resistivity and higher breakdown field strength because of the reduction in Pi-bonding. Still further, the amorphous carbon layers 120 were able to withstand higher temperatures (e.g., greater than 650° C.) for periods of at least 15 minutes, or even 30 minutes or even 60 minutes, with a thermal shrinkage of less than 10% or even less than 5%.

It was further discovered that the breakdown voltages of the deposited amorphous carbon layers 120 can be increased by reducing the temperature of the deposition process. FIG. 7 shows the breakdown voltage of different amorphous carbon layers 120 that are each deposited at different temperatures, keeping the rest of the deposition parameters constant. It is also seen that the breakdown voltage of the different carbon layers 120 reduced from over 60 volts at a deposition temperature of 100° C. to about 25 volts at 300° C. This graph showed a non-linear response between deposition temperature and breakdown voltage. Further, this represented an unexpected result of more than a twofold drop in breakdown voltage by decreasing the deposition temperature by 200° C. Thus, it was determined that it was desirable to maintain the temperature of the deposition process to less than 110° C. to deposit an amorphous carbon layer 120 having a dielectric breakdown voltage of at least about 60 volts.

Referring back to FIG. 6, the amorphous carbon layers 120 also exhibited high breakdown voltage and low leakage current simultaneously, which is unusual and unexpected. Thus, in one desirable version, the variable resistance memory element comprises an amorphous carbon layer 120 comprising a hydrogen content of at least about 30 atomic percent and a maximum leakage current of less than about 1×10⁻⁹ amps. It is believed that these desirable properties of a dielectric breakdown voltage of at least about 60 volts as well as a maximum leakage current of less than about 1×10⁻⁹ amps result from the increased hydrogen content in the amorphous carbon layers 120. Specifically, it has been determined that such properties for the amorphous carbon layer 120 can be obtained with a hydrogen content in the layer 120 of at least about 30 atomic percent. The amorphous carbon layer 120 also has a volume isotropic shrinkage of less than 5% after annealing at 650° C. in nitrogen for 1 hour to provide low thermal shrinkage along with the desirable resistance change properties.

Although exemplary embodiments of the present invention are shown and described, those of ordinary skill in the art may devise other embodiments which incorporate the present invention and which are also within the scope of the present invention. Furthermore, the terms below, above, bottom, top, up, down, first and second and other relative or positional terms are shown with respect to the exemplary embodiments in the figures and are interchangeable. Therefore, the appended claims should not be limited to the descriptions of the preferred versions, materials, or spatial arrangements described herein to illustrate the invention.

What is claimed is:

1. An electronic device comprising:
(a) a substrate;
(b) a variable resistance memory element on the substrate, the variable resistance memory element comprising:
(i) an amorphous carbon layer comprising:
(1) a hydrogen content of at least about 30 atomic percent; and
(2) a maximum leakage current of less than about 1×10⁻⁹ amps; and
(ii) a pair of electrodes about the amorphous carbon layer.

2. An electronic device of claim 1, wherein the amorphous carbon layer comprises a volume isotropic shrinkage of less than 5% after annealing at 650° C. in a nitrogen atmosphere for 1 hour.

3. An electronic device of claim 1, wherein the amorphous carbon layer comprises an extinction coefficient of from about 0.03 to about 0.1 at a wavelength of 633 nanometers.

4. An electronic device of claim 1, wherein the amorphous carbon layer comprises a first resistivity level that is greater than 400 ohm-cm.

5. An electronic device of claim 1, wherein the amorphous carbon layer, in a thickness of about 2000 angstroms, comprises a sheet resistance of greater than 1×10⁸ ohms/square.

6. An electronic device of claim 1, wherein the amorphous carbon layer, in a thickness of about 2000 angstroms, comprises a sheet resistance of from about 1×10⁷ ohms/square to about 1×10⁸ ohms/square.

7. An electronic device of claim 1, wherein the amorphous carbon layer comprises a thickness of from about 100 to about 1000 angstroms.

8. An electronic device of claim 1, wherein the amorphous carbon layer comprises a density of from about 1.40 to about 1.55 g/cc.

9. An electronic device of claim 1, wherein the amorphous carbon layer comprises a stress level of from about −100 to about −400 MPa.

10. An electronic device of claim 1, wherein the electrodes are adapted to apply a set voltage across the amorphous carbon layer to change the resistivity of the amorphous layer from a first resistivity level to a second resistivity level.

11. An electronic device of claim 1, wherein the pair of electrodes each have a thickness of from about 20 to about 1000 angstroms.

12. An electronic device of claim 1, wherein the pair of electrodes comprise tungsten.

13. An electronic device of claim 1, wherein the electronic device includes a memory.

14. An electronic device according to claim 13, wherein the memory is in a packaged integrated circuit.

15. An electronic device comprising an amorphous carbon layer disposed on a substrate, the amorphous carbon layer comprising a hydrogen content of at least about 30 atomic percent and a maximum leakage current of less than about 1×10⁻⁹ amps, the amorphous carbon layer formed by a method comprising:
(a) placing the substrate into a process zone;
(b) maintaining the substrate at a temperature of less than 300° C.;
(c) introducing into the process zone, a process gas comprising a carbon-containing gas and a diluent gas;
(d) maintaining the process gas at a pressure of from about 0.5 to about 20 Torr; and
(e) forming a plasma from the process gas.

16. A method of depositing an amorphous carbon layer on a substrate, the method comprising:
(a) placing the substrate into a process zone;
(b) maintaining the substrate at a temperature of less than 300° C.;
(c) introducing into the process zone, a process gas comprising a carbon-containing gas and a diluent gas, and maintaining the process gas at a pressure of from about 0.5 to about 20 Torr; and
(d) forming a plasma from the process gas by applying a first RF power at a first frequency to electrodes about the process zone, and applying a second RF power to the substrate at a second frequency, the second frequency being lower than the first frequency.

17. A method according to claim 16 wherein the process conditions are set to deposit an amorphous carbon layer comprising a hydrogen content of at least about 30 atomic percent and a maximum leakage current of less than about 1×10⁻⁹ amps.

18. A method according to claim 16 wherein the first frequency is about 13.5 MHz, and the second frequency is less than 1 MHz.

19. A method according to claim 16 wherein the process zone comprises electrodes, and wherein (d) comprises applying the first RF power at the first frequency to the electrodes, and applying the second RF power at the second frequency to the substrate.

20. A method according to claim 18 wherein the method further includes spacing the electrodes at a spacing distance of from about 200 mils to about 1000 mils.

21. A method according to claim 16 comprising applying each of the first and second RF powers at power levels of from about 100 to about 2000 watts.

22. A method according to claim 16 wherein the carbon-containing gas comprises CₓH_{y} where x is from 1 to 10 and y is from 2 to 30, or mixtures of such gases.

23. A method according to claim 16 wherein the carbon-containing gas comprises CₓH_{y}N_{z} where x is from 1 to 10, y is from 2 to 30, and z is from 1 to 10, or mixtures of such gases.

24. A method according to claim 16 wherein the carbon-containing gas comprises triethylamine.

25. A method according to claim 16 wherein the diluent gas comprises argon, helium, hydrogen, or nitrogen.
